(19) United States
(12) Patent Application Publication
(10) Pub. No.: US 2024/0096692 A1
(43) Pub. Date: Mar. 21, 2024

(54) HYBRID DAMASCENE INTERCONNECT STRUCTURE FOR SIGNAL AND POWER VIA CONNECTIONS

(71) Applicant: International Business Machines Corporation, Armonk, NY (US)

(72) Inventors: Nicholas Anthony Lanzillo, Wynantskill, NY (US); Albert M. Chu, Nashua, NH (US); Lawrence A. Clevenger, Saratoga Springs, NY (US)

(21) Appl. No.: 17/933,874

(22) Filed: Sep. 21, 2022

(51) Int. Cl. H01L 21/768; H01L 23/522

(52) U.S. Cl. CPC H01L 21/76816; H01L 21/76807; H01L 21/76834; H01L 21/76883; H01L 23/5226; H01L 21/76843

(57) ABSTRACT

A semiconductor device and formation thereof. The semiconductor device includes a first via in a metal layer, wherein the first via is a single damascene structure. The semiconductor device further includes a second via in the metal level, wherein the second via is a dual damascene structure.

### BACKGROUND OF THE INVENTION

The present invention relates generally to the field of semiconductor devices, and more particularly to signal and power interconnects in the same metal layer being formed from a hybrid damascene process.

As integrated circuits move to smaller technology nodes, simultaneous patterning of signal and power interconnect(s) in the same metal layer of a semiconductor device becomes increasingly challenging, especially when forming interconnects in the lower metal layers.

### SUMMARY

According to one embodiment of the present invention, a semiconductor interconnect structure is provided. The semiconductor interconnect structure includes a first via in a metal layer. The first via is a single damascene structure. The semiconductor interconnect structure further includes a second via in the metal layer. The second via is a dual damascene structure.

According to another embodiment of the present invention, a method for forming a semiconductor interconnect structure is provided. The method includes forming a first via in a metal layer using a single damascene process. The method further includes forming a second via in the metal layer using a dual damascene process.

### BRIEF DESCRIPTION OF THE SEVERAL VIEWS OF THE DRAWINGS

The following detailed description, given by way of example and not intend to limit the disclosure solely thereto, will best be appreciated in conjunction with the accompanying drawings, in which:

FIG. 1 illustrates a cross-sectional view of an initial semiconductor structure, generally designated 100, including a dielectric layer 120 formed on a substrate 110 in accordance with at least one embodiment of the present invention.

FIG. 2 illustrates a cross-sectional view of semiconductor structure 100 depicted in FIG. 1 after performing subsequent processing steps, generally designated 200, in accordance with at least one embodiment of the present invention.

FIG. 3 illustrates a cross-sectional view of semiconductor structure 200 depicted in FIG. 2 after performing subsequent processing steps, generally designated 300, in accordance with at least one embodiment of the present invention.

FIG. 4 illustrates a cross-sectional view of semiconductor structure 300 depicted in FIG. 1 after performing subsequent processing steps, generally designated 400, in accordance with at least one embodiment of the present invention.

FIG. 5 illustrates a cross-sectional view of semiconductor structure 400 depicted in FIG. 4 after performing alternative subsequent processing steps, generally designated 500, in accordance with at least one embodiment of the present invention.

FIG. 6 illustrates a cross-sectional view of semiconductor structure 500 depicted in FIG. 5 after subsequent processing steps, generally designated 600, in accordance with at least one embodiment of the present invention.

FIG. 7 illustrates a cross-sectional view of semiconductor structure 600 depicted in FIG. 6 after subsequent processing steps, generally designated 700, in accordance with at least one embodiment of the present invention.

FIG. 8 illustrates a cross-sectional view of semiconductor structure 700 depicted in FIG. 7 after subsequent processing steps, generally designated 800, in accordance with at least one embodiment of the present invention.

FIG. 9 illustrates a cross-sectional view of semiconductor structure 800 depicted in FIG. 8 after subsequent processing steps, generally designated 900, in accordance with at least one embodiment of the present invention.

FIG. 10 illustrates a cross-sectional view of semiconductor structure 900 depicted in FIG. 9 after subsequent processing steps, generally designated 1000, in accordance with at least one embodiment of the present invention.

When viewed as ordered combinations, FIGS. 1-10 illustrate both (i) semiconductor devices and (ii) the methods for forming such semiconductor devices, in accordance with illustrative embodiments.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Embodiments of the present invention recognize that the particular process used to form different types of interconnect structures in the same metal layer may result in certain tradeoffs. For example, although a single damascene process used to form vias may advantageously allow for the formation of vias that carry signals (hereinafter referred to as “signal vias”) having a narrower pitch (and thereby increased signal density), the same single damascene process negatively results in vias that carry power (hereinafter referred to as “power vias”) having increased via resistance, and consequently, the need for higher capacitance. In another example, although a dual damascene process used to form via/line interconnects may advantageously result in decreased via resistance (and consequently the need for lower capacitance) between the via/line interface in power vias, the same dual damascene process disadvantageously results in the formation of signal vias having a wider pitch (and thereby decreased signal density).

Accordingly, embodiments of the present invention provide for a semiconductor device having interconnect structures in the same metal layer formed from a hybrid damascene process. The hybrid damascene process involves the formation of at least one via/line signal interconnect structure in a metal layer by a single damascene process and the formation of at least one via/line power interconnect structure in the same metal layer by a dual damascene process. This ultimately results in an improved semiconductor interconnect structures having high density via/line signal interconnects and low resistance via/line power interconnects formed in the same metal layer.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

As described below, in conjunction with FIGS. 1-10, embodiments of the present invention include semiconductor interconnect structures and methods of forming such semiconductor interconnect structures, and in particular, semiconductor interconnect structures having signal and power via/line interconnect structures in the same metal layer formed from a hybrid damascene process. The methods described below in conjunction with FIGS. 1-10 may be incorporated into typical semiconductor memory device fabrication processes. As such, when viewed as ordered combinations, FIGS. 1-10 illustrate methods for forming semiconductor interconnect structures having signal and power via/line interconnect structures in the same metal layer that maximize signal density of signal interconnect structures while reducing resistance in power interconnect structures between the via/line interface.

According to one embodiment of the present invention, a method of forming a hybrid damascene interconnect structure for signal and power via connections is disclosed. The method includes: forming a first via in a metal layer using a single damascene process; and forming a second via in the metal layer using the dual damascene process.

The method further includes forming a first metal line in the metal layer using a single damascene process; and forming a second metal line in the metal layer using a dual damascene process.

In an embodiment, forming the first via includes forming a first via opening in a first dielectric layer; depositing a first metal liner along a sidewall and bottom surface of the first via opening; and filling a remainder of the first via opening with a metal.

In an embodiment, forming the first metal line, the second metal line, and the second via in the metal layer includes: depositing a second dielectric layer; simultaneously forming a first line opening and a second line opening in the second dielectric layer; forming a second via opening in the first dielectric layer after forming the second line opening; depositing a second metal liner along a sidewall and bottom surface of the first line opening, along a sidewall of the second line opening, and along a sidewall and a bottom surface of the second via opening; and filling a remainder of the first line opening and the second line opening with the metal.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

As used herein, the term signal via may refer to a via that carries signals between two different lines located in two different metal layers. For example, a signal via may transfer signals from a first line located in a first metal layer to a second line located in a second metal layer.

As used herein, the term power via may refer to a via that carries power between two different lines located in two different metal layers. For example, a power via may transfer signals from a first line located in a first metal layer to a second line located in a second metal layer.

As used herein, the term signal line may refer to a line (i.e., metal line or interconnect) in the back-end-of-the-line (BEOL) of a semiconductor device used to distribute signals between two or more individual devices (e.g., transistors, capacitors, or resistors).

As used herein, the term power line may refer to a line (i.e., metal line or interconnect) in the back-end-of-the-line (BEOL) of a semiconductor device used to distribute power (i.e., power and/or ground) between two or more individual devices (e.g., transistors, capacitors, or resistors).

As used herein, the term metal layer may refer to one of a plurality of metal wiring levels in the BEOL of a semiconductor device. A metal layer may include a via formed in a first dielectric layer connected to a line formed in a second dielectric layer. For example, if a signal via formed in a first dielectric layer is connected to signal line formed in a second dielectric layer, the resulting signal via/line structure shall be said to be formed in the same metal layer. Similarly, if a power via formed in a first dielectric layer is connected to a power line formed in a second dielectric layer, the resulting power via/line structure shall be said to be formed in the same metal layer.

As used herein, the term single damascene structure may refer to a via or line formed from a single damascene process.

As used herein, the term dual damascene structure may refer to a via or line formed from a dual damascene process.

The present invention will now be described in detail with reference to the Figures. FIGS. 1-10 include various cross-sectional views depicting illustrative steps of a method for manufacturing semiconductor devices and the resulting semiconductor devices according to select embodiments of the present invention. One having ordinary skill in the art will appreciate that there are many options available for the formation of the structures described herein and that the following discussion does not limit embodiments to only the techniques described herein.

Referring now to FIG. 1, FIG. 1 illustrates a cross-sectional view of an initial semiconductor structure, generally designated 100, including a dielectric layer 120 formed on a substrate 110, in accordance with at least one embodiment of the present invention. In some embodiments, substrate 110 may include a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 110 may include one or more interconnect levels of a multilayered interconnect structure, such as a back-end-of-the-line (BEOL) structure. A BEOL structure is typically where the individual semicondcutor devices in the FEOL structure are interconnected with one another. In such embodiments, each interconnect level may include one or more electrically conductive structures embedded in an interconnect dielectric material. For example, the one or more interconnect levels of a multilayered interconnect structure may be formed from any generally known semiconductor materials, such as silicon, gallium arsenide, or germanium.

Dielectric layer 120 may be composed of an inorganic dielectric material or an organic dielectric material. In some embodiments, dielectric layer 120 may be porous. In other embodiments, dielectric layer 120 may be non-porous. In some embodiments, dielectric layer 120 may have a dielectric constant (all dielectric constants mentioned herein are measured relative to a vacuum, unless otherwise stated) that is about 4.0 or less. In an embodiment, dielectric layer 120 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as dielectric layer 120 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, 0 and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

Dielectric layer 120 can be deposited on substrate 110 using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), spin-on coating, sputtering, and/or plating. Dielectric layer 120 can have a thickness from 50 nm to 250 nm. However, other thicknesses that are less than 50 nm, or greater than 250 nm can also be employed in embodiments of the present invention.

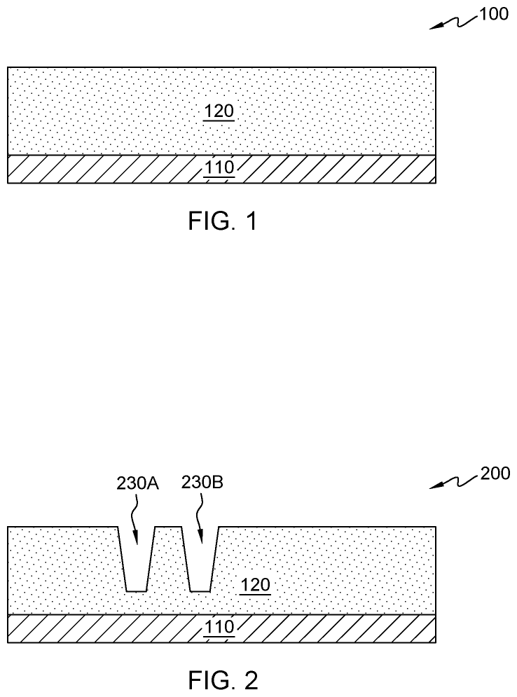

FIG. 2 illustrates a cross-sectional view of semiconductor structure 100 depicted in FIG. 1 after performing subsequent processing steps, generally designated 200, in accordance with at least one embodiment of the present invention. As depicted in FIG. 2, via openings 230A and 230B are formed following the patterning of dielectric layer 120 using a single damascene process. For example, a hard mask layer is formed by depositing a hard mask material (e.g., silicon nitride, titanium nitride, tantalum nitride, or any suitable metal-containing material) onto the surface of dielectric layer 120. The hard mask layer can be formed utilizing a deposition process including, but not limited to, CVD, PECVD, ALD, physical vapor deposition (PVD) or sputtering.

A photoresist material (not depicted) is then deposited onto the surface of the hard mask layer. The photoresist material can be applied by any suitable techniques, including, but not limited to, coating or spin-on techniques. A photomask (not depicted) patterned with shapes defining via openings 230A and 230B to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the hard mask layer. Dry etch techniques (for example, an anisotropic etch process, such as reactive ion etch) may be employed to selectively remove portions of the hard mask layer to form the patterned hard mask. After formation of patterned hard mask, the photoresist material may be stripped from the patterned hard mask by ashing or other suitable processes. The resulting structure may be subjected to a wet clean.

The resulting patterned hard mask, which acts as an etch mask, is formed such that the portions of the underlying dielectric layer 120 corresponding to via openings 230A and 230B to be formed are left exposed, while the remaining portions of the underlying structure of dielectric layer 120 are protected by the patterned hard mask. During patterning of dielectric layer 120 using the patterned hard mask, the physically exposed portions of dielectric layer 120 are removed by an anisotropic etching process such as, for example, reactive ion etching (RIE), ion beam etching (IBE), chemical wet etching, or a combination of IBE and chemical wet etching. The etch removes the exposed portions of dielectric layer 120 that are not protected by the patterned hard mask to form via openings 230A and 230B.

Via openings 230A and 230B extend vertically downwards through dielectric layer 120 and towards substrate 110. The depth(s) of via openings 230A and 230B can be controlled by using a timed etching process. In some embodiments, and as shown, via openings 230A and 230B may extend partially downwards through dielectric layer 120. In other embodiments, via openings 230A and 230B may extend downwards through the entire depth of dielectric layer 120. In various embodiments, via openings 230A and 230B may have the same depth or different depths.

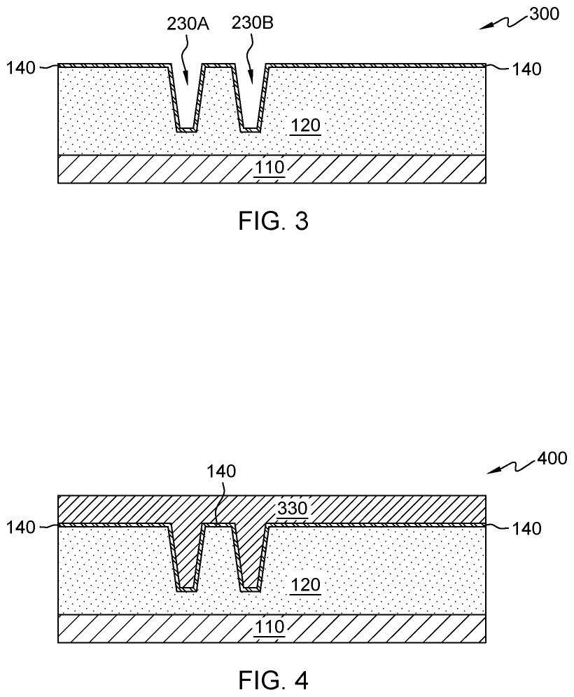

FIG. 3 illustrates a cross-sectional view of semiconductor structure 200 depicted in FIG. 2 after performing subsequent processing steps, generally designated 300, in accordance with at least one embodiment of the present invention. In some embodiments, and as depicted by semiconductor structure 300, an optional metal liner 140 is conformally deposited on the exposed surfaces of the patterned dielectric layer 120. Metal liner 140 may include one or more thin layers of material such as, for example, tantalum (Ta), tantalum nitride (TaN), titanium nitride (TiN), cobalt (Co), ruthenium (Ru), tungsten (W), tungsten nitride (WN), titanium-tungsten (TiW), tungsten nitride (WN) manganese (Mn), manganese nitride (MnN) or other liner materials (or combinations of liner materials) such as RuTaN, Ta/TaN, CoWP, NiMoP, or NiMoB which are suitable for the given application. The thin metal liner serves as a barrier diffusion layer and adhesion layer. A conformal layer of metal liner 140 may be deposited using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating. The thickness of metal liner 140 may vary depending on the deposition process used, as well as the material employed. In some embodiments, metal liner 140 may have a thickness from 2 nm to 50 nm. However, other thicknesses that are less than 2 nm, or greater than 50 nm can also be employed in embodiments of the present invention, as long as metal liner 140 does not entirely fill via openings 230A and 230B.

In some embodiments, an optional plating seed layer (not depicted) can be formed on metal liner 140 as well. The optional plating seed layer is employed to selectively promote subsequent electroplating of a pre-selected conductive metal or metal alloy. The optional plating seed layer may be composed of Cu, a Cu alloy, Jr, an Jr alloy, Ru, a Ru alloy (e.g., TaRu alloy) or any other suitable noble metal or noble metal alloy having a low metal-plating overpotential. Typically, a Cu or Cu alloy plating seed layer is employed when a Cu metal is to be subsequently formed within via openings 230A and 230B. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, or greater than 80 nm can also be employed in embodiments of the present invention, as long as the optional plating seed layer does not entirely fill via openings 230A and 230B.

FIG. 4 illustrates a cross-sectional view of semiconductor structure 300 depicted in FIG. 3 after performing subsequent processing steps, generally designated 400, in accordance with at least one embodiment of the present invention. Semiconductor structure 400 is achieved by depositing a metal filler 330 (e.g., via atomic layer deposition, chemical vapor deposition, plating, electroplating, or any other suitable deposition techniques) on the exposed surfaces of metal liner 140. Via openings 230A and 230B (depicted in FIG. 3) are filled with metal filler 330 until metal filler 330 is at least substantially coplanar with the top surface of dielectric layer 120. In an embodiment, metal filler 330 may be a metal or metal alloy including, but not limited to, copper (Cu), aluminum (Al), ruthenium (Ru), rhodium (Rh), iridium (Jr), tungsten (W), molybdenum (Mo), nickel (Ni), or an alloy thereof, such as, for example, a Cu—Al alloy. In those embodiments in which a thin conformal copper (Cu) seed layer (not depicted) is deposited over the surface of metal liner 140 using, for example, PVD, metal filler 330 is subsequently formed by electroplating of Cu to fill openings 230A-230C. In those embodiments in which metal liner 140 is not used, metal filler 330 is deposited directly onto the exposed surfaces of the patterned dielectric layer 120. Metal filler 330 can be formed utilizing a deposition process such as, for example, CVD, PECVD, sputtering, chemical solution deposition or plating. In an embodiment, a bottom-up plating process is employed in forming metal filler 330.

In an embodiment, metal filler 330 is formed within and filling via openings 230A and 230 (depicted in FIG. 3) by depositing metal filler 330, followed by a thermal annealing. For example, the thermal annealing can be a furnace anneal, rapid thermal anneal, flash anneal, or laser anneal. In an embodiment, for furnace anneal and rapid thermal anneal, the annealing temperature can range from 150° C. to 450° C. for furnace anneal and rapid thermal anneal and the anneal duration can range from 10 minutes to one hour. In an embodiment, for flash anneal/laser anneal, the annealing temperature can be higher (e.g., from 450° C. to 1000° C.), but the anneal duration is much shorter (e.g., ranging from 100 nanoseconds to 100 milliseconds).

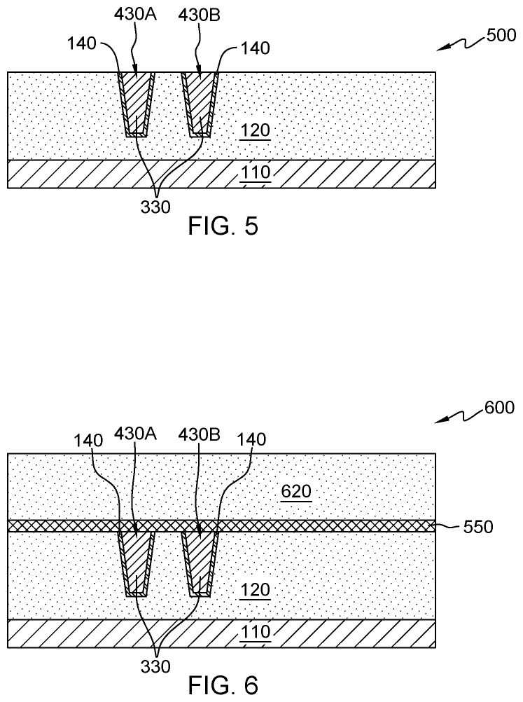

FIG. 5 illustrates a cross-sectional view of semiconductor structure 400 depicted in FIG. 4 after performing subsequent processing steps, generally designated 500, in accordance with at least one embodiment of the present invention. Semiconductor structure 500 is achieved following a planarization process such as, for example, chemical mechanical planarization or polishing (CMP) and/or grinding, which is used to remove portions of metal liner 140, optional plating seed layer (not depicted), and metal filler 330 (collectively referred to as “overburden material”) that is present outside of via openings 230A and 230B (depicted in FIG. 3) to form vias 430A and 430B, respectively. The planarization stops at the top surface of dielectric layer 120, such that metal liner 140, optional plating seed layer (not depicted), and metal filler 330 are substantially coplanar with the top surface of dielectric layer 120.

Vias 430A and 430B are single damascene structures formed from a single damascene process. In some embodiments, and as depicted in FIG. 5, vias 430A and 430B are signal vias. In other embodiments, vias 430A and 430B may be power vias or a combination of signal and power vias.

FIG. 6 illustrates a cross-sectional view of semiconductor structure 500 depicted in FIG. 5 after performing subsequent processing steps, generally designated 600, in accordance with at least one embodiment of the present invention. Semiconductor structure 600 is achieved by forming an optional capping layer 550 on the exposed surfaces of semicondcutor structure 500 depicted in FIG. 5, followed by a dielectric layer 620. Capping layer 550 and dielectric layer 620 can be formed using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), spin-on coating, sputtering, and/or plating. Capping layer 550 can include, but is not limited to, silicon dioxides (SiO2), silicon nitrides (Si3N4), silicon carbides (SiC), nitrogen-hydrogen doped silicon carbides (SiC)(N,H), or any other insulators which are suitable for the given application. Dielectric layer 620 can include any of the dielectric materials used to form dielectric layer 120 as described above with reference to FIG. 1. In some embodiments, dielectric layer 620 is composed of a same dielectric material as dielectric layer 120. In other embodiments, dielectric layer 620 is composed of a dielectric material that is compositionally different from the dielectric material used to form dielectric layer 120. Dielectric layer 620 has a thickness that can be in the thickness range previously mentioned for dielectric layer 120.

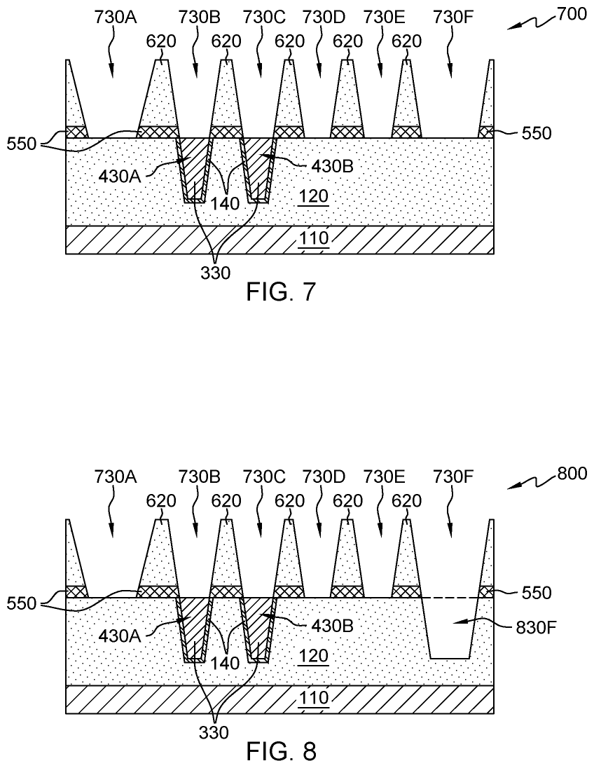

FIG. 7 illustrates a cross-sectional view of semiconductor structure 600 depicted in FIG. 6 after performing subsequent processing steps, generally designated 700, in accordance with at least one embodiment of the present invention. Line openings 730A-730E are formed following the patterning of dielectric layer 620 using a single damascene process, while line opening 730F and via opening 830F (depicted in FIG. 8) are formed using a dual damascene process.

For example, the single damascene process includes forming a patterned hard mask on top of dielectric layer 620. The patterned hard mask layer can be formed using the same processes and materials for forming via openings 230A and 230B as described above with reference to FIG. 2. The resulting patterned hard mask, which acts as an etch mask, is formed such that the portions of the underlying dielectric layer 620 corresponding to line openings 730A-730F to be formed are left exposed, while the remaining portions of the underlying structure of dielectric layer 620 are protected by the patterned hard mask. During patterning of dielectric layer 620 using the patterned hard mask, the physically exposed portions of dielectric layer 620 are removed by an anisotropic etching process such as, for example, reactive ion etching (RIE), ion beam etching (IBE), chemical wet etching, or a combination of IBE and chemical wet etching. The etch removes the exposed portions of dielectric layer 620 that are not protected by the patterned hard mask to form line openings 730A-730F.

As depicted by semiconductor structure 700 of FIG. 7, line openings 730A, and 730D-730F extend vertically downwards through dielectric layer 620 such that the top surface of dielectric layer 120 is exposed. Line openings 730B and 730C extend vertically downwards through dielectric layer 620 such that the top portion of metal filler 330 of vias 430A and 430B is exposed.

In some embodiments, and as depicted in FIG. 7, line openings 730A, and 730D-730F may extend downwards through the entire depth of dielectric layer 620. In other embodiments, line openings 730A, and 730D-730F may extend partially downwards through dielectric layer 620 or fully through dielectric layer 620 and partially through capping layer 650. In various embodiments, line openings 730A, and 730d-730F may have the same depth or different depths.

FIG. 8 illustrates a cross-sectional view of semiconductor structure 700 depicted in FIG. 7 after performing subsequent processing steps, generally designated 800, in accordance with at least one embodiment of the present invention. After forming line openings 730A-730F (depicted in FIG. 7) using a single damascene process, via opening 830F is formed using a dual damascene process. For example, another patterned hard mask (not depicted) is formed on the exposed surface of dielectric layer 120 within line opening 730F. The patterned hard mask may be formed using the same processes and materials for forming line openings 730A-730F as described above with reference to FIG. 7. The resulting patterned hard mask, which acts as an etch mask, is formed such that the portion of the underlying dielectric layer 120 corresponding to via opening 830F to be formed is left exposed, while the remaining portions of the underlying structure of dielectric layer 120 are protected by the patterned hard mask. The portions of dielectric layer 120 left uncovered by the patterned hard mask are removed by an anisotropic etching process such as, for example, reactive ion etching (RIE), ion beam etching (IBE), chemical wet etching, or a combination of IBE and chemical wet etching. The etch removes the exposed portions of dielectric layer 120 that are not protected by the patterned hard mask.

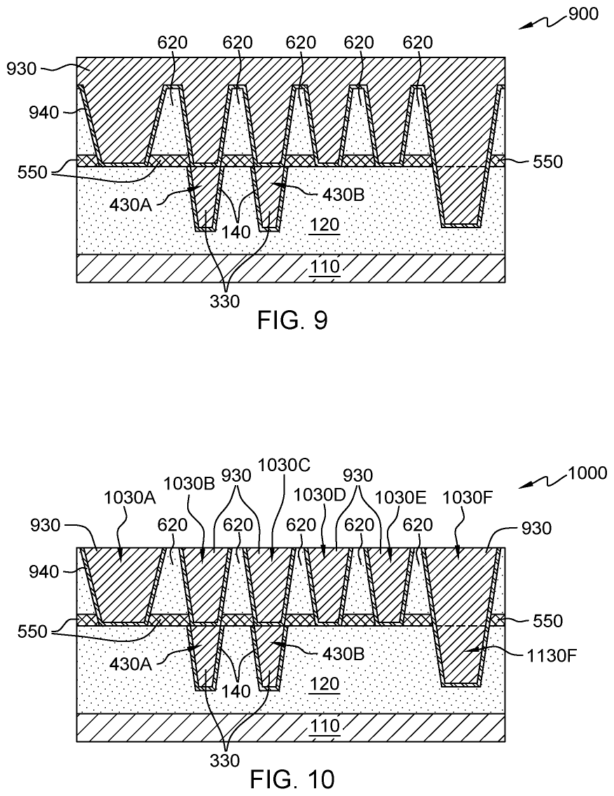

FIG. 9 illustrates a cross-sectional view of semiconductor structure 800 depicted in FIG. 8 after performing subsequent processing steps, generally designated 900, in accordance with at least one embodiment of the present invention. Semiconductor structure 900 is achieved by conformally depositing an optional metal liner 940 on the exposed surfaces of the patterned dielectric layer 120 and the patterned dielectric layer 620, followed by the deposition of a metal filler layer 930 on the exposed surfaces of metal liner 940. Metal liner 940 may be formed using the same processes and materials used to form metal liner 140 as described above with reference to FIG. 3. The thickness of metal liner 940 may vary depending on the deposition process used, as well as the material employed. In some embodiments, metal liner 940 may have a thickness from 2 nm to 50 nm. However, other thicknesses that are less than 2 nm, and greater than 50 nm can also be employed in embodiments of the present invention, as long as metal liner 940 does not entirely fill line openings 730A-730F and via opening 830F.

In some embodiments, an optional plating seed layer (not depicted) can be formed on metal liner 940 as well. The optional plating seed layer is employed to selectively promote subsequent electroplating of a pre-selected conductive metal or metal alloy. The optional plating seed layer may be composed of Cu, a Cu alloy, Ir, an Ir alloy, Ru, a Ru alloy (e.g., TaRu alloy) or any other suitable noble metal or noble metal alloy having a low metal-plating overpotential. The optional plating seed layer can be formed by a conventional deposition process including, for example, CVD, PECVD, ALD, or PVD. The thickness of the optional plating seed layer may vary depending on the material of the optional plating seed layer, as well as the technique used in forming the same. Typically, the optional plating seed layer may have a thickness from 2 nm to 80 nm. However, other thicknesses that are less than 2 nm, and greater than 80 nm can also be employed in embodiments of the present invention, as long as the optional plating seed layer does not entirely fill line openings 730A-730F and via opening 830F.

Metal filler 930 is formed such that line openings 730A-730F and via opening 830F are filled with metal filler 930 until metal filler 930 is at least substantially coplanar with the top surface of dielectric layer 620. Metal filler 930 may be formed using the same processes and materials used to form metal filler 930 as described above with reference to FIG. 4. In those embodiments in which a thin conformal copper (Cu) seed layer (not depicted) is deposited over the surface of metal liner 940 using, for example, PVD, metal filler 930 is subsequently formed by electroplating of Cu to fill line openings 730A-730F and via opening 830F. In those embodiments in which metal liner 940 is not used, metal filler 930 is deposited directly onto the exposed surfaces of the patterned dielectric layer 120 and the patterned dielectric layer 620.

FIG. 10 illustrates a cross-sectional view of semiconductor structure 900 depicted in FIG. 9 after performing subsequent processing steps, generally designated 1000, in accordance with at least one embodiment of the present invention. Semiconductor structure 1000 is achieved following a planarization process such as, for example, chemical mechanical planarization or polishing (CMP) and/or grinding, which is used to remove portions of metal liner 940, optional plating seed layer (not depicted), and metal filler 930 (collectively referred to as “overburden material”) that is present outside of line openings 730A-730F (depicted in FIG. 8) to form lines 1030A-1030F and via 1130F, respectively. The planarization stops at the top surface of dielectric layer 620, such that metal liner 940, optional plating seed layer (not depicted), and metal filler 930 are substantially coplanar with the top surface of dielectric layer 620.

As further depicted in FIG. 10, metal liner 940 is formed along a bottom surface of lines 1030B and 1030C, such that metal liner 940 is in contact with a top surface of vias 430A and 430B respectively. In other words, metal liner 940 is located between the interface of lines 1030B and 1030C and vias 430A and 430B, respectively. On the other hand, metal liner 940 is not formed along a bottom surface of line 1030F, such that a bottom surface of line 1030F is in contact with a top surface of via 1130F. Accordingly, no metal liner 940 is located between the interface of line 1030F and via 1130F.

Vias 430A and 430B are single damascene structures formed from a single damascene process, while via 1130F is a dual damascene structure formed from a dual damascene process. In some embodiments, and as depicted in FIG. 10, vias 430A and 430B are signal vias and via 1130F is a power via. As further depicted in FIG. 10, line vias 430A and 430B are narrower than via 1130F. Thus, in those embodiments in which vias 430A and 430B are signal vias and via 1130F is a power, via, it can be said that the signal vias are narrower than the power via. In some embodiments, and as depicted in FIG. 10, a bottom surface of the signal vias (430A and 430B) and a bottom surface of the power via (1130F) are at similar depths within dielectric layer 120. In other embodiments, a bottom surface of the signal vias (430A and 430B) and a bottom surface of the power via (1130F) may be at different depths within dielectric layer 120.

Lines 1030A-1030E are single damascene structures formed from a single damascene process. In some embodiments, and as depicted in FIG. 10, line 1030A is a power line and lines 1030B-1030E are signal lines. Line 1030F and via 1130F are dual damascene structures formed from a dual damascene process. In some embodiments, and as depicted in FIG. 10, line 1030F is a power line and via 1130 is a power via. As further depicted in FIG. 10, lines 1030B-1030E are narrower than lines 1030A and 1030F, respectively. Thus, in those embodiments in which lines 1030B-1030E are signal lines and lines 1030A and 1030F are power lines, it can be said that the signal lines are narrower than the power lines.

In some embodiments, and as depicted in FIG. 10, the signal vias (430A and 430B) and the power via (1130F) are formed from similar materials. In other embodiments, the signal vias (430A and 430B) may be formed from a different material(s) than the power via (1130F). In some embodiments, and as depicted in FIG. 10, the signal lines (1030B-1030E) and the power lines (1030A and 1030F) are formed from similar materials. In other embodiments, the signal lines (1030B-1030E) may be formed from a different material(s) than the power lines (1030A and 1030F).

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as, for instance, “side”, “over”, “perpendicular”, “tilted”, etc., as used herein refer to relative location and orientation of various portions of the structures with respect to one another, and are not intended to suggest that any particular absolute orientation with respect to external objects is necessary or required.

The foregoing specification also describes processing steps. While some of the steps may be in an ordered sequence, others may in different embodiments from the order that they were detailed in the foregoing specification. The ordering of steps when it occurs is explicitly expressed, for instance, by such adjectives as, “ordered”, “before”, “after”, “following”, and others with similar meaning.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art.

What is claimed is:

1. A semiconductor device, comprising:
a first via in a metal layer, wherein the first via is a single damascene structure; and
a second via in the metal level, wherein the second via is a dual damascene structure.

2. The semiconductor device of claim 1, further comprising:
a first metal line in the metal layer, wherein the first metal line is a single damascene structure; and
a second metal line in the metal layer, wherein the second metal line is a dual damascene structure.

3. The semiconductor device of claim 1, wherein the first via is narrower than the second via.

4. The semiconductor device of claim 1, wherein the first via is used to carry signals.

5. The semiconductor device of claim 1, wherein the second via is used to carry power.

6. The semiconductor device of claim 2, wherein the first metal line is narrower than the second metal line.

7. The semiconductor device of claim 2, wherein the first metal line is used to carry signals.

8. The semiconductor device of claim 2, wherein the second metal line is used to carry power.

9. The semiconductor device of claim 2, wherein a liner is formed along a bottom surface of the first metal line, and further wherein the liner is in contact with a top surface of the first via.

10. The semiconductor device of claim 2, wherein a liner is not formed along a bottom surface of the second metal line, and further wherein a bottom surface of the second metal line is in contact with a top surface of the second via.

11. The semiconductor device of claim 1, wherein the first via and the second via are formed from similar materials.

12. The semiconductor device of claim 1, wherein the first via and the second via are formed from different materials.

13. The semiconductor device of claim 2, wherein the first via and the first metal line are formed from similar materials.

14. The semiconductor device of claim 2, wherein the first via and the first metal line are formed from different materials.

15. The semiconductor device of claim 2, wherein a bottom surface of the first via and a bottom surface of the second via are at similar depths within the metal layer.

16. The semiconductor device of claim 2, wherein a bottom surface of the first via and a bottom surface of the second via are at different depths within the metal layer.

17. A method of forming a semiconductor device, comprising:
forming a first via in a metal layer using a single damascene process; and
forming a second via in the metal layer using a dual damascene process.

18. The method of claim 17, further comprising:
forming a first metal line in the metal layer using a single damascene process; and
forming a second metal line in the metal layer using a dual damascene process.

19. The method of claim 18, wherein forming the first via in the metal layer includes:
forming a first via opening in a first dielectric layer;
depositing a first metal liner along a sidewall and bottom surface of the first via opening; and
filling a remainder of the first via opening with a metal.

20. The method of claim 19, wherein forming the first metal line, the second metal line, and the second via in the metal layer includes:
depositing a second dielectric layer;
simultaneously forming a first line opening and a second line opening in the second dielectric layer;
forming a second via opening in the first dielectric layer after forming the second line opening;
depositing a second metal liner along a sidewall and bottom surface of the first line opening, along a sidewall of the second line opening, and along a sidewall and a bottom surface of the second via opening; and
filling a remainder of the first line opening and the second line opening with the metal.
